(19) United States
(12) Patent Application Publication
(10) Pub. No.: US 2024/0341194 A1
(43) Pub. Date: Oct. 10, 2024

(54) SYSTEM AND METHODS FOR LOW VOLTAGE SENSING IN PIEZOELECTRIC HAPTICS

(71) Applicant: Microchip Technology Incorporated, Chandler, AZ (US)

(72) Inventors: Razvan Costache, Dambovita (RO); Miguel Angel Salcedo, Watsonville, CA (US)

(73) Assignee: Microchip Technology Incorporated, Chandler, AZ (US)

(21) Appl. No.: 18/232,953

(22) Filed: Aug. 11, 2023

Related U.S. Application Data
(60) Provisional application No. 63/457,233, filed on Apr. 5, 2023.

(51) Int. Cl. H10N 30/00; G01L 1/16; H10N 30/80

(52) U.S. Cl. CPC H10N 30/101; G01L 1/16; H10N 30/802

(57) ABSTRACT

A device includes a high-voltage amplifier to amplify a bursted signal and may couple to a driver circuit to drive a piezoelectric actuator. During the on-time of the bursted signal, a feedback circuit may compensate for non-idealities in the system and may equalize the signal at the actuator and the output of the high-voltage amplifier. During the off-time of the bursted signal, a signal conditioning circuit may sense a difference signal between the signal at the actuator and the signal at the high-voltage amplifier output and may interpret this difference signal as pressure applied to the piezoelectric actuator.

### PRIORITY

This application claims priority to commonly owned U.S. Patent Application No. 63/457,233 filed on Apr. 5, 2023, the entire contents of which are hereby incorporated by reference for all purposes.

### FIELD OF THE INVENTION

The present disclosure relates to systems and methods for sensing in applications utilizing a piezoelectric element for haptics.

### BACKGROUND

Piezoelectric materials may generate a mechanical response when an electric charge is applied across the material. A piezoelectric material which functions in this manner may be termed a piezoelectric actuator. Piezoelectric actuators may be utilized in haptic applications. In haptic applications, a user may experience this mechanical response as a sensation of touch. An electric charge applied across the piezoelectric actuator may cause the element to vibrate. In a haptic application, applying signals of different voltages and frequencies may result in different vibration responses. These different responses may be felt by a user as a button press, switch toggle or other physical responses.

Haptics may be utilized in an automotive application as part of a steering wheel or console interface on a touchscreen. Physical buttons may be replaced with a piezoelectric actuator and a force sensor.

A piezoelectric actuator may be modeled as a capacitor. In order to generate sufficient physical displacement of the actuator, the actuator must be driven by a high voltage signal. Typical drive voltages may be in excess of 100 Volts.

In a haptic application, a piezoelectric actuator may also be used as a sensing element. In one of various applications, a user may apply force to the piezoelectric actuator which may be detected as a voltage. In such applications, there is both a drive path and a sensing path. The drive path generates the high-voltage signal to drive the piezoelectric actuator, and the sensing path senses pressure applied by the user. The sensing path is a low-voltage path, sensing small changes in current, voltage or capacitance as a user's touch is applied to the actuator.

During the time when the high-voltage signal is driving the piezoelectric actuator, any low-voltage components in the sensing path must be protected against the high voltages across the actuator. In one of various examples, a switch may remove the connection between the sensing path and the actuator during the time when the high-voltage signal is driving the piezoelectric actuator. In this case, there is no sensing while the actuator is driven with a high-voltage signal.

There is a need for a system which may allow for sensing in the sensing region while the high-voltage actuator is driven.

### SUMMARY

The examples herein enable a circuit which may sense force on a high-voltage haptic actuator while the actuator is being driven with a high-voltage signal.

According to one aspect, a device includes a high-voltage amplifier to receive a periodic signal at a first input and a driver circuit coupled to the output of the high-voltage amplifier. A feedback circuit may be coupled from the output of the driver circuit to a second input of the high-voltage amplifier and a sense resistor may have a first node coupled to the output of the driver circuit and a second node coupled to a piezoelectric actuator. A signal conditioning circuit may have a first input capacitively coupled to the output of the high-voltage amplifier and a second input capacitively coupled to the piezoelectric actuator. The signal conditioning circuit may generate a first output and a second output. A signal conditioning amplifier may receive the first output and the second output of the signal conditioning circuit, and the signal conditioning amplifier may generate a first output and a second output based on a difference between the first output of the signal conditioning circuit and the second output of the signal conditioning circuit. An analog-to-digital converter may generate a digital output based on the first output and the second output of the signal conditioning amplifier and the digital output may be representative of a level of pressure applied to the piezoelectric actuator.

According to one aspect, a system includes a digital-to-analog converter to receive a periodic digital signal from a processor and to generate a periodic analog signal. A high-voltage amplifier may receive the periodic analog signal at a first input and a driver circuit may be coupled to the output of the high-voltage amplifier. A feedback circuit may be coupled from the output of the driver circuit to a second input of the high-voltage amplifier and a sense resistor with a first node coupled to the output of the driver circuit and a second node coupled to a piezoelectric actuator. A signal conditioning circuit with a first input capacitively coupled to the output of the high-voltage amplifier and a second input capacitively coupled to the piezoelectric actuator may generate a first output and a second output. A signal conditioning amplifier may receive the first output and the second output of the signal conditioning circuit, and the signal conditioning amplifier may generate a first output and a second output based on a difference between the first output of the signal conditioning circuit and the second output of the signal conditioning circuit. An analog-to-digital converter may generate a digital output based on the output of the signal conditioning amplifier, the digital output representative of a level of pressure applied to the piezoelectric actuator. The analog-to-digital converter may output the digital output to a processor.

According to one aspect, a method includes operations of: generating a periodic signal at the output of a digital-to-analog converter, amplifying the periodic signal to generate a high-voltage drive signal, driving a piezoelectric actuator with the high-voltage drive signal, sensing a difference signal between the voltage at the piezoelectric actuator and the high-voltage drive signal, processing the difference signal to determine a level of force applied to the piezoelectric actuator.

### BRIEF DESCRIPTION OF THE DRAWINGS

FIG. 1 illustrates one of various examples of a device for driving a piezoelectric actuator and sensing force.

FIG. 2 illustrates waveforms representative of a system for driving a piezoelectric actuator and sensing force.

FIG. 3 illustrates a method of driving a piezoelectric actuator and sensing force applied to the piezoelectric actuator.

### DETAILED DESCRIPTION

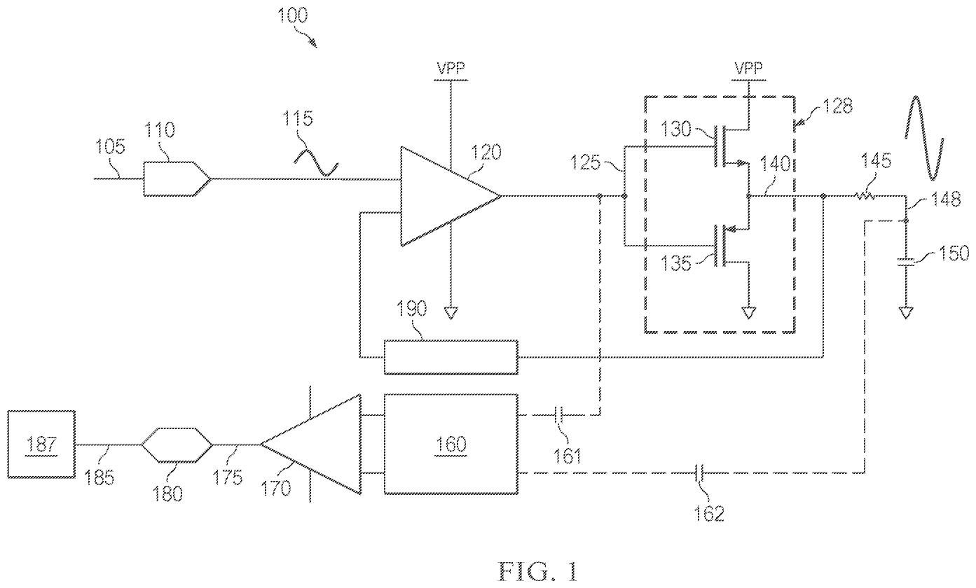

FIG. 1 illustrates one of various examples of a device 100 for driving a piezoelectric actuator 150 to generate a haptic response and for sensing force applied to piezoelectric actuator 150.

Digital input signal 105 may be input to a digital-to-analog converter (DAC) 110. DAC 110 may convert digital input signal 105 into an analog signal 115. High-voltage amplifier 120 may apply gain to analog signal 115 to generate drive signal 125.

Drive signal 125 may be input to driver circuit 128. Driver circuit 128 may include high-side transistor 130 and low-side transistor 135 in an inverter configuration. High-side transistor 130 is illustrated as an NMOS transistor, but this is not intended to be limiting. High-side transistor 130 may be a PMOS transistor, a bipolar transistor, or another type of transistor. Low-side transistor 135 is illustrated as a PMOS transistor, but this is not intended to be limiting. Low-side transistor 135 may be an NMOS transistor, a bipolar transistor, or another type of transistor. Driver circuit 128 may include other circuit components not shown explicitly in FIG. 1.

In the example illustrated in FIG. 1, driver circuit 128 is illustrated as a separate component from high-voltage amplifier 120. In other examples, driver circuit 128 may be integrated into high-voltage amplifier 120.

High-voltage output signal 140 may be the output of driver circuit 128. High-voltage output signal 140 may be an analog signal with a peak-to-peak voltage greater than 50 Volts. High-voltage output signal 140 may drive sense resistor 145. Sense resistor 145 may be coupled to piezoelectric actuator 150. Piezoelectric actuator 150 is illustrated with a capacitor symbol since the electrical response of a piezoelectric actuator is typically modelled as a capacitance. The use of the capacitor symbol is not intended to represent the physical design of piezoelectric actuator 150. Piezoelectric actuator 150 may generate a mechanical response when driven with a high-voltage signal at node 148.

Feedback circuit 190 may be used in a feedback path from high-voltage output signal 140 to the inverting input of high-voltage amplifier 120. The feedback path may compensate for any non-idealities and non-linearities in high-voltage amplifier 120, high-side transistor 130 and low-side transistor 135.

Coupling capacitors 161 and 162 may couple, respectively, drive signal 125 and node 148 to signal conditioning circuit 160. Signal conditioning circuit 160 may include filters, amplifiers or other circuits to modify the signals at the input of signal conditioning circuit 160. Coupling capacitors 161 and 162 enable high-voltage signals at drive signal 125 and node 148 to be coupled to low-voltage signal conditioning circuit 160 without damaging circuitry in signal conditioning circuit 160.

Amplifier 170 may amplify the outputs of signal conditioning circuit 160 and may convert the outputs of signal conditioning circuit 160 to a signal-ended output 175.

Single-ended output 175 may be input to analog-to-digital converter (ADC) 180. ADC 180 may also be termed ADC FSENSE as this is the ADC for the sense path. ADC 180 may output a digital signal 185. Digital signal 185 may be input to processor 187 or another circuit capable to receive digital signal 185. Processor 187 may be a digital signal processor (DSP), a microcontroller, an embedded processor or another type of processor.

Signal conditioning circuit 160, amplifier 170 and ADC 180 may enable device 100 to sense force applied to actuator 150. Force applied to actuator 150 may be detected as the voltage difference between the desired output at drive signal 125 and the actual signal at actuator 150, sensed at node 148.

In operation, in haptic applications, an actuator may be driven with a high-voltage signal at a very low duty cycle. As one of various examples, an actuator may be driven with a high voltage signal for 1 msec. This short period may be termed the on-time of the actuator. The actuator may then be idled, or not driven, for 199 msec. This idle period may be termed the off-time of the actuator. This 200 msec period may be repeated while the actuator is driven. This repeated pattern of on-time and off-time may be termed a bursted signal or a pulsed signal. This example is not intended to be limiting. In other examples, an actuator may be driven with a high voltage signal for a different period of time, and may be idled for a different period of time. During the on-time of the actuator, the high-voltage amplifier 120 may output a high-voltage signal, feedback circuit 190 may equalize the voltages at drive signal 125 and high-voltage output signal 140. During this time, the inputs to signal conditioning circuit 160 may be equal. During the off-time of the actuator, the output voltage of high-voltage amplifier 120 may drop below a predetermined threshold and the feedback loop through feedback circuit 190 may no longer operate effectively to equalize the voltages at drive signal 125 and high-voltage output signal 140. A user may apply physical pressure to actuator 150, which may be measured as a voltage at node 148. The voltage difference between coupling capacitor 162 and coupling capacitor 161 may be input to signal conditioning circuit 160, amplified by amplifier 170 and converted by ADC 180. The output of ADC 180, digital signal, may represent the difference between the voltage at high-voltage output signal 140 and the voltage at the piezoelectric element 150. This difference may be reflective of the pressure applied by a user to the piezoelectric element 150. If this difference exceeds a predetermined threshold, it may be interpreted as a button press or other physical input by the user.

The example illustrated in FIG. 1 represents a single channel of information driving a single actuator, but this is not intended to be limiting. In one of various examples, a multi-channel DAC may drive multiple high-voltage amplifiers and transistors to drive multiple actuators. A multi-channel signal conditioning circuit and multichannel ADC may convert signals received from the multiple actuators.

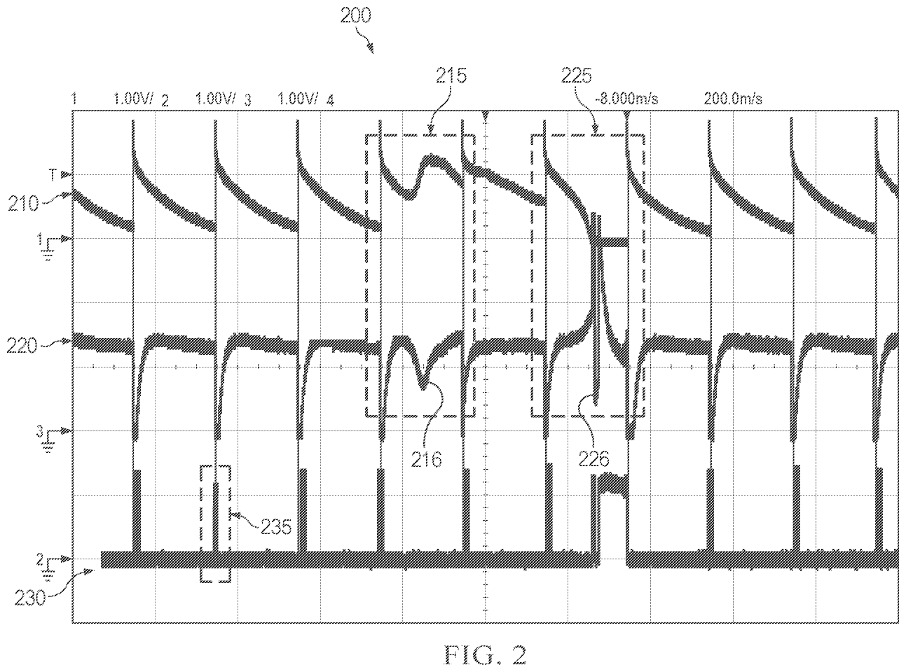

FIG. 2 illustrates waveforms representative of a system for driving a piezoelectric actuator and sensing force. Waveforms illustrated in FIG. 2 may be representative of voltages at components of device 100 as described and illustrated in FIG. 1.

Signal trace 210 may represent the signal across actuator 150. Signal trace 220 may represent single-ended output 175, the output of amplifier 170. Signal trace 230 may represent drive signal 125, the output of high-voltage amplifier 120.

In operation, DAC 110 may drive a bursted signal onto node 115. The exact frequency and amplitude of the pulsed signal may represent a physical response, including but not limited to a button press, movement of a slider, or a vibration alert. In one of various examples, the pulsed signal may have a period of 200 msec, with the pulsed signal on-time of 1 msec. This pulsed signal may generate a charge pulse 235 at the output of high-voltage amplifier 120, as illustrated in trace 230. Trace 220 may reflect the difference in voltage between coupling capacitor 161 and coupling capacitor 162 during the on-time of the bursted signal, and may settle to a nominal voltage during the off-time of the bursted signal. The charge pulse on trace 230 may drive the gate of high-side transistor 130 and may drive the gate of low-side transistor 135, which may drive actuator 150 as shown in trace 210. The capacitance of actuator 150 results in the exponential decay illustrated in trace 210.

At location 215, a user may apply pressure to actuator 150. This pressure may be reflected at trace 220 as a deviation from the periodic nature of trace 220. Where trace 220 typically settles to a nominal voltage, location 216 illustrates a change in the voltage reflective of the pressure applied to actuator 150. The perturbation in trace 220 at location 216 may be converted by ADC 180 and, if the perturbation exceeds a programmable threshold, the perturbation may be interpreted as a user pressing the actuator.

At location 225, a user may release the pressure on the actuator. This release of pressure may be sensed at trace 220 as a deviation from the periodic nature of trace 220. Where trace 220 typically settles to a nominal voltage, location 226 illustrates a change in the voltage reflective of the release of pressure applied to actuator 150. The perturbation in trace 220 at location 226 may be converted by ADC 180 and, if the perturbation exceeds a programmable threshold, the perturbation may be interpreted as a user releasing pressure on the actuator.

The signals illustrated in FIG. 2 may enable smooth haptic effects without glitches because there are no switches to enable or disable the low-voltage paths.

The specific voltages and frequencies illustrated in FIG. 2 are not intended to be limiting. Other examples may utilize signals of different voltages and different frequencies.

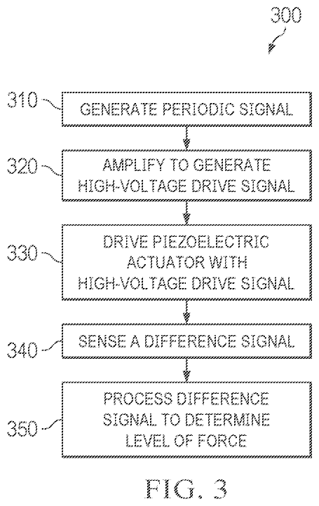

FIG. 3 illustrates a method 300 for driving a piezoelectric actuator and sensing force.

At operation 310, a periodic signal may be generated at the output of a digital-to-analog converter. At operation 320, the periodic signal may be amplified to generate a high-voltage drive signal. At operation 330, a piezoelectric actuator may be driven with the high-voltage drive signal.

At operation 340, a difference signal may be sensed between the voltage at the piezoelectric actuator and the high-voltage drive signal. At operation 350, the difference signal may be processed to determine a level of force applied to the piezoelectric actuator.

1. A device comprising:
a high-voltage amplifier to receive a periodic signal at a first input;
a driver circuit coupled to the output of the high-voltage amplifier;
a feedback circuit coupled from the output of the driver circuit to a second input of the high-voltage amplifier;
a sense resistor with a first node coupled to the output of the driver circuit and a second node coupled to a piezoelectric actuator;
a signal conditioning circuit with a first input capacitively coupled to the output of the high-voltage amplifier and a second input capacitively coupled to the piezoelectric actuator, the signal conditioning circuit to generate a first output and a second output;
a signal conditioning amplifier to receive the first output and the second output of the signal conditioning circuit, the signal conditioning amplifier to generate a first output and a second output based on a difference between the first output of the signal conditioning circuit and the second output of the signal conditioning circuit, and
an analog-to-digital converter to generate a digital output based on the first output and the second output of the signal conditioning amplifier, the digital output representative of a level of pressure applied to the piezoelectric actuator.

2. The device as claimed in claim 1, the driver circuit comprising an inverter circuit.

3. The device as claimed in claim 1, the driver circuit comprising an amplifier circuit.

4. The device as claimed in claim 1, the signal conditioning circuit comprising a low-pass filter.

5. The device as claimed in claim 1, the feedback circuit to compensate for differences between the periodic signal and the output of the driver circuit.

6. A system comprising:
a digital-to-analog converter to receive a periodic digital signal from a processor and to generate a periodic analog signal;
a high-voltage amplifier to receive the periodic analog signal at a first input;
a driver circuit coupled to the output of the high-voltage amplifier;
a feedback circuit coupled from the output of the driver circuit to a second input of the high-voltage amplifier;
a sense resistor with a first node coupled to the output of the driver circuit and a second node coupled to a piezoelectric actuator;
a signal conditioning circuit with a first input capacitively coupled to the output of the high-voltage amplifier and a second input capacitively coupled to the piezoelectric actuator, the signal conditioning circuit to generate a first output and a second output;
a signal conditioning amplifier to receive the first output and the second output of the signal conditioning circuit, the signal conditioning amplifier to generate a first output and a second output based on a difference between the first output of the signal conditioning circuit and the second output of the signal conditioning circuit, and
an analog-to-digital converter to generate a digital output based on the output of the signal conditioning amplifier, the digital output representative of a level of pressure applied to the piezoelectric actuator, and to output the digital output to the processor.

7. The system as claimed in claim 6, the driver circuit comprising an inverter circuit.

8. The system as claimed in claim 6, the driver circuit comprising an amplifier circuit.

9. The system as claimed in claim 6, the signal conditioning circuit comprising a low-pass filter.

10. The system as claimed in claim 6, the feedback circuit to compensate for differences between the periodic signal and the output of the driver circuit.

11. A method comprising:
generating a periodic signal at the output of a digital-to-analog converter;
amplifying the periodic signal to generate a high-voltage drive signal;
driving a piezoelectric actuator with the high-voltage drive signal;
sensing a difference signal between the voltage at the piezoelectric actuator and the high-voltage drive signal;
processing the difference signal to determine a level of force applied to the piezoelectric actuator.

12. The method as claimed in claim 11, the periodic signal comprising a bursted sinusoidal signal.

13. The method as claimed in claim 11, the amplifying a periodic signal comprising inputting the periodic signal to a high-voltage amplifier.

14. The method as claimed in claim 11, comprising coupling the high-voltage signal to the input of the high-voltage amplifier via a feedback circuit.

15. The method as claimed in claim 11, the feedback circuit to compensate for differences between the periodic signal and the output of the driver circuit.

16. The method as claimed in claim 11, the sensing a difference signal comprising a signal conditioning circuit coupled to a signal conditioning amplifier.

17. The method as claimed in claim 11, the sensing a difference signal comprising an analog-to-digital converter coupled to a processor.

18. The method as claimed in claim 17, the processing the difference signal comprising processing, in the processor, the output of the analog-to-digital converter.
